(19) United States
(12) Patent Application Publication
(10) Pub. No.: US 2007/0091571 A1
(43) Pub. Date: Apr. 26, 2007

(54) Heat exchanger with fins configured to retain a fan

(76) Inventors: Christopher G. Malone, Loomis, CA (US); Glenn C. Simon, Auburn, CA (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/259,213

(22) Filed: Oct. 25, 2005

(51) Int. Cl. H05K 7/20

(52) U.S. Cl. 361/699

(57) ABSTRACT

In a cooling apparatus, a heat exchanger comprises tubing and multiple fins formed onto the tubing. The fins are formed to position and retain one or more cooling fans.

### BACKGROUND OF THE INVENTION

A liquid loop heat exchange cooling system may be used to cool electronics components for various applications. Some applications with high-power components, for example servers, high-performance computers, work stations, and the like, may most benefit from the cooling system. A liquid loop system may enable higher density system packaging and management of higher component power levels and power densities.

### SUMMARY

In accordance with an embodiment of a cooling apparatus, a heat exchanger comprises tubing and multiple fins formed onto the tubing. The fins are formed to position and retain one or more cooling fans.

### BRIEF DESCRIPTION OF THE DRAWINGS

Embodiments of the invention relating to both structure and method of operation may best be understood by referring to the following description and accompanying drawings:

FIG. 1 is an overhead pictorial view depicting an embodiment of a cooling apparatus with fins configured to hold a fan to a heat exchanger;

FIG. 2 is an overhead pictorial view showing an embodiment of a cooling apparatus configured to form a plenum space between the heat exchanger and the fans;

FIG. 3 is an overhead pictorial view showing an embodiment of a cooling apparatus including a heat exchanger with a retaining fin formed to retain and position more than one fan;

FIG. 4 is an overhead pictorial view illustrating an embodiment of a cooling apparatus with a configuration adapted to avoid or eliminate air recirculation in a multiple-fan arrangement;

FIG. 5 is a perspective pictorial diagram depicting an embodiment of a fin which may be used in a heat exchanger to facilitate combined usage of fans with the heat exchanger;

FIGS. 6A and 6B are perspective pictorial diagrams, respectively omitting and including fans, illustrating an embodiment of a retaining fin adapted to retain and position a fan relative to a heat exchanger;

FIGS. 7A and 7B are perspective pictorial diagrams showing exploded and combined views of an embodiment of a cooling apparatus with fins configured to retain a cooling fan separated from a heat exchanger by a plenum space;

FIGS. 8A and 8B are perspective pictorial diagrams illustrating exploded and combined views of another embodiment of a cooling apparatus with fins configured to retain a cooling fan attached to a top surface of a heat exchanger;

FIG. 8C is a perspective pictorial diagram showing an embodiment of a cooling apparatus with multiple cooling fans attached to a side surface of a heat exchanger;

FIG. 8D is a perspective pictorial diagram depicting an embodiment of a cooling apparatus with multiple cooling fans attached to a side surface of a heat exchanger and a plenum space separating the fans and heat exchanger; and

FIG. 9 is a schematic mixed pictorial and block diagram illustrating an embodiment of an electronic system that incorporates a cooling apparatus with one or more fans retained by heat exchanger fins.

### DETAILED DESCRIPTION

One challenge faced by system designers is placement of cooling fans in a liquid loop heat exchanger cooling system given extreme space constraints inside modern computer systems. Traditionally, fans are mounted relative to heat exchangers using bulky sheet metal or plastic clamps. In various illustrative embodiments, heat exchanger fins may be used to address such space constraints and/or to improve other aspects of liquid loop heat exchanger cooling systems by functioning both as a heat exchanger radiating surface and as an attachment or positioning element or clip.

A heat exchanger comprises multiple fins which are typically bonded or press-fit onto tubing containing a cooling fluid. Selectively extended and folded fins may be used to perform gross positioning and engagement of the fans. In some embodiments, extensions and folds in the fins may also be used for engaging power connectors and/or retaining fans, cables, and other structures during shock and retention events.

Usage of heat exchanger fins for structural retention and shock resistance enables fan positioning and retention without usage of additional materials, enabling implementation of the maximum number of fans per linear inch. Furthermore, retaining fans using fin material adds thermally-useful surface area to improve thermal performance.

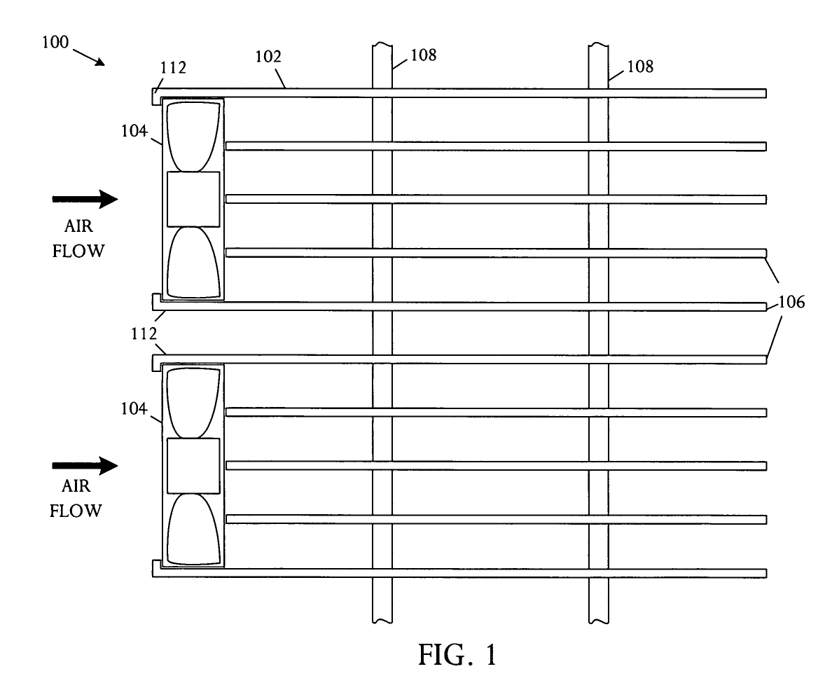

Referring to FIG. 1, an overhead pictorial view depicts an embodiment of a cooling apparatus 100 with fins 106 configured to hold a fan 104 to a heat exchanger 102. The fins 106 may be configured to retain and position structures including fans 104 and power connectors, as well to hold the structures in shock and vibration conditions. The illustrative cooling apparatus 100 comprises a heat exchanger 102 including tubing 108 and multiple fins 106 formed onto the tubing 108. The fins 106 are formed to position and retain one or more cooling fans 104. In various embodiments, the fins 106 are typically bonded or press-fit onto the tubing 108. Fins 106 may be constructed from any suitable material, typically including aluminum alloys, brass, carbon steel, stainless steel, copper, and other materials.

The multiple fins 106 include selected fins that function as retaining fins 112. Most of the fins 106 are planar sheets arranged in parallel that extend to a common plane intersecting the plane of the fins 106. The retaining fins 112 are shown extending past the common plane to form structures adapted to position and retain the fans 104. The extended retaining fins 112 are configured to hold and position the fans 104 in a manner that enables elimination of other structural materials. Because the retaining fins 112 are constructed from material adapted for heat radiation, the number and density of fins 106 may be reduced or minimized.

From another perspective, the heat exchanger 102 may be configured in an arrangement that increases heat radiation to the passing airflow. Because the retaining fins 112 are fabricated from the same material as the fins 106, the surface area adapted for heat radiation is increased.

The heat exchanger 102 functions by transferring heat from a first fluid, for example cooling fluid circulating in the tubing 108, to a second fluid, such as air flowing through the fins 106, without intermixing the fluids. The tubing 108 is typically connected to a pump and the tubing 108 and pump, in combination, function to circulate the cooling fluid. The multiple fins 106 are connected to the tubing 108 in a manner that transfers heat from the cooling fluid to the fins 106. The fins 106 function to radiate heat from the cooling fluid to air driven past the fins 106 by operation of a fan or fans 104. The fins 106 are arranged in a configuration that further functions to position and retain the one or more fans 104 relative to the heat exchanger 102.

The cooling apparatus 100 may further comprise one or more cooling fans 104.

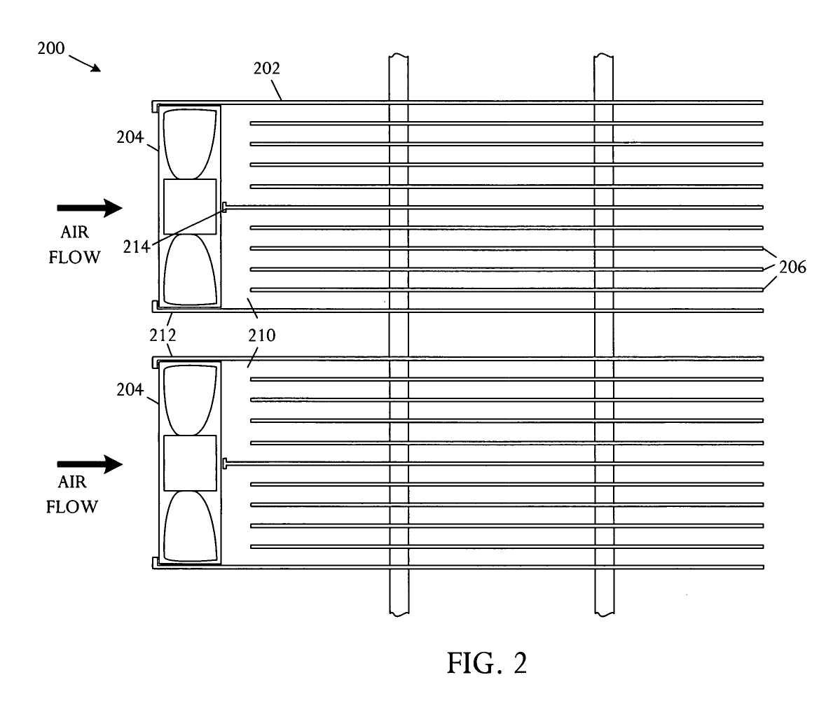

Referring to FIG. 2, an overhead pictorial view shows an embodiment of a cooling apparatus 200 configured to form a plenum space 210 between the heat exchanger 202 and the one or more fans 204. One or more retaining fins 212 of the multiple fins 206 are formed in a configuration that functions to retain the one or more fans 204 in a selected position relative to the heat exchanger 202. The cooling apparatus 200 further comprises one or more plenum fins 214 formed to hold the one or more fans 204 a selected distance, for example called a plenum distance, from the heat exchanger 202 whereby the plenum space 210 is formed between the fans 204 and the heat exchanger 202.

Usage of the plenum fin 214 enables formation of the plenum space 210 in a compact arrangement using few or minimal structural hardware. Accordingly, the illustrative arrangement enables formation of the plenum space 210 at reduced or minimal cost.

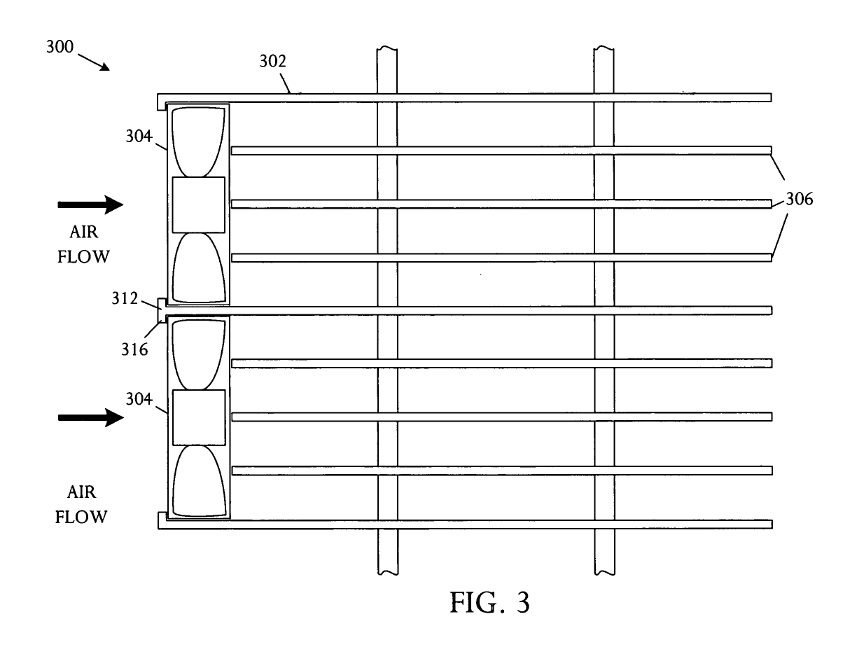

Referring to FIG. 3, an overhead pictorial view shows an embodiment of a cooling apparatus 300 including a heat exchanger 302 with a retaining fin 312 formed to retain and position more than one fan 304. The illustrative cooling apparatus 300 further comprises a retaining fin 312 of the multiple fins 306 including a planar fin positioned between adjacent fans 304 and extending longer than other fins 306 to an end portion. The retaining fin 312 is bent or otherwise formed into flanges 316 extending substantially perpendicular to a central planar fin 312 in opposing directions whereby the flanges retain two cooling fans 304.

Fan retention using a single retaining fin 312 rather than multiple fins as depicted in FIGS. 1 and 2 enables tighter fan pitch and more efficient space usage, as well as possible reduction in component cost. Usage of the single retaining fin 312 may also reduce or eliminate recirculation of heated air.

Systems with multiple fans can recirculate air through fin gaps between fans. Bending or folding fins until adjacent fins touch may eliminate recirculation.

The retaining fin configuration 312 may be constructed to eliminate gaps between fans 404 that may otherwise allow recirculation of heated air and possible system overheating. The retaining fin configuration 312 may also be used to eliminate wasted fin area.

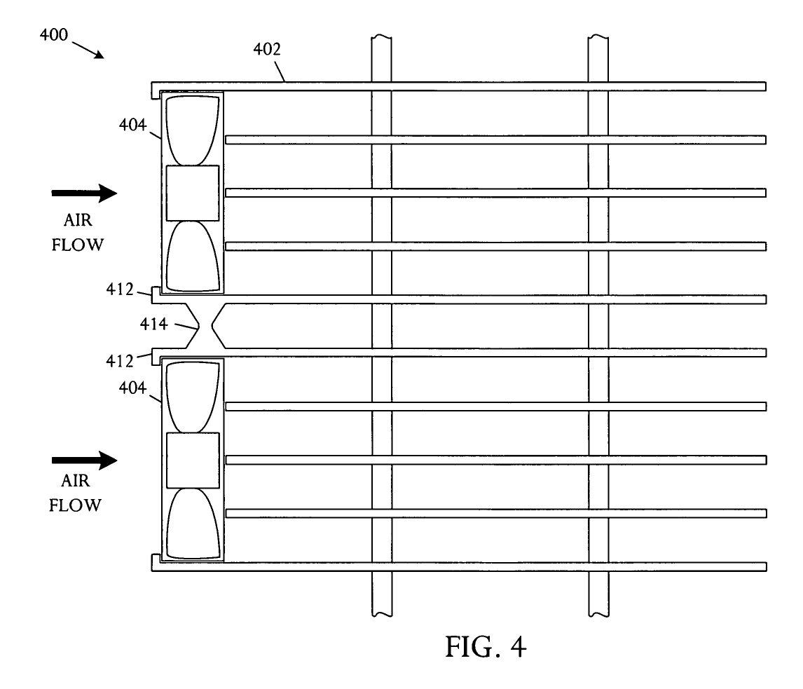

Referring to FIG. 4, an overhead pictorial view shows an embodiment of a cooling apparatus 400 with a configuration adapted to avoid or eliminate air recirculation in a multiple-fan arrangement. The fans 404 form an airflow pathway through a heat exchanger 402 driving heated air radiated from the heat exchanger 402 out of a system through venting. Gaps between adjacent fans 404 may enable recirculation of heated air back to the input air source, potentially resulting in system overheating. The illustrative configuration of the cooling apparatus 400 includes a blocking structure 414 between retaining fins 412 arranged to retain and position adjacent fans 404. The blocking structure 414 prevents air recirculation by closing a gap between fans 404.

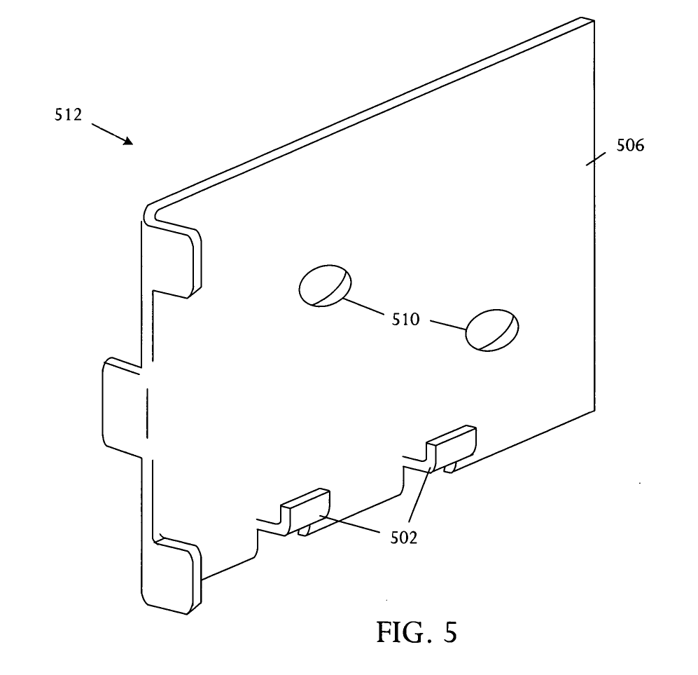

Referring to FIG. 5, a perspective pictorial diagram illustrates an example embodiment of a retaining fin 512 which may be used in a heat exchanger to facilitate combined usage of fans with the heat exchanger. One or more of the fins 512 may be extended and folded to form structures 502 adapted for positioning and engaging power connectors. The structures 502 may also be configured for retaining a fan or fans and power connectors during occurrence of shock and vibration events. The fin 512 is shown as a planar sheet 506 fabricated from a heat radiating material. The sheet 506 has apertures 510 arranged to pass through cooling fluid tubing.

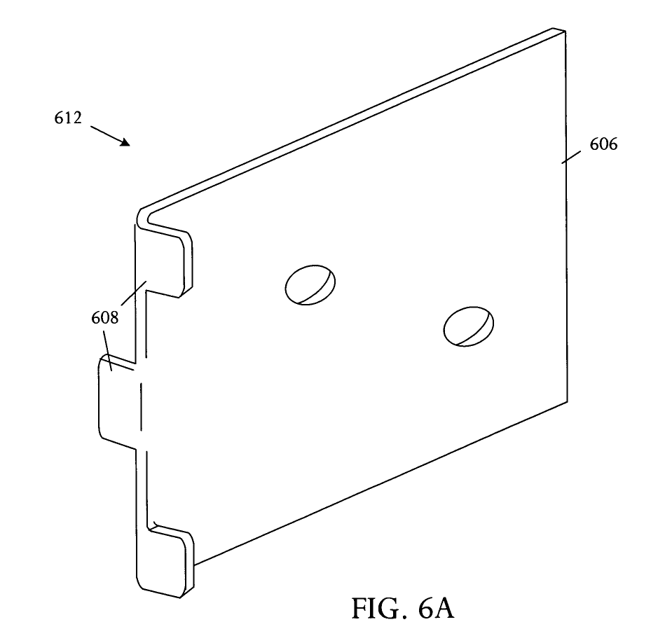

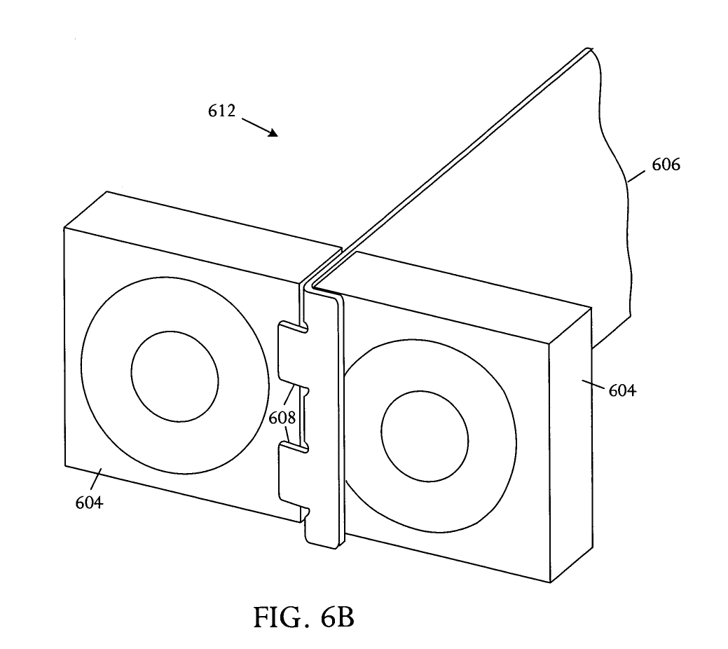

Referring to FIG. 6A, a perspective pictorial diagram shows an embodiment of a retaining fin 612 adapted to retain and position a fan relative to a heat exchanger. A cooling apparatus may be constructed by forming multiple fins of a heat exchanger in a configuration adapted to position and hold one or more cooling fans. The illustrative retaining fin 612 is formed as a planar sheet 606 fabricated from a heat radiating material and having apertures through which tubing may be inserted. The illustrative retaining fin 612 extends relative to other fins of a heat exchanger a distance appropriate to retain and position a fan. The most distal portion of the planar sheet 606 is folded or bent essentially perpendicular to the plane of the sheet 606 to form tabs 608 for holding the fan. The illustrative retaining fin 612 has an end that is cut and folded in a configuration suitable for containing a fan on each side of the planar sheet 606.

Referring to FIG. 6B, a perspective pictorial diagram illustrates an embodiment of the retaining fin 612 in position retaining a pair of fans 604. The cooling apparatus may be further formed by positioning one or more cooling fans at a selected location and retaining the cooling fans 604 at the location.

Referring again to FIG. 5, selected fins 512 may be folded to form engagement structures 502 to position and engage power connectors and to retain the fans and power connectors for shock and vibration events.

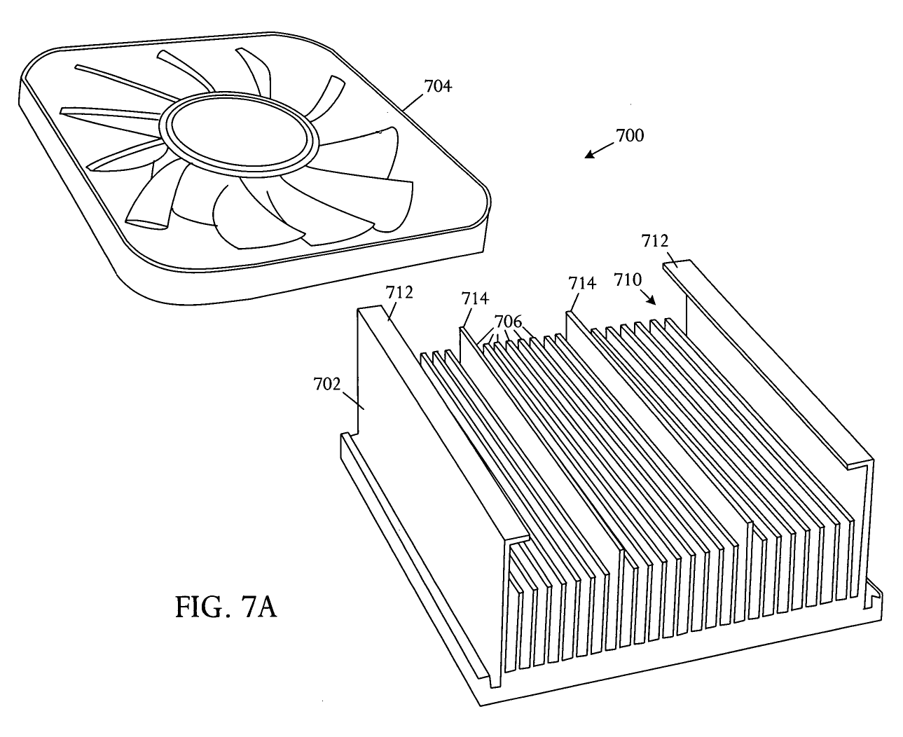

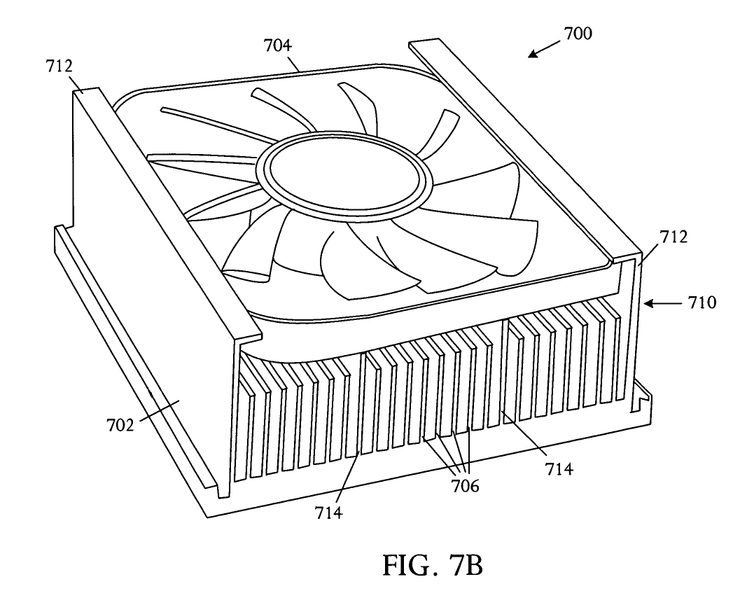

Referring to FIGS. 7A and 7B, perspective pictorial diagrams illustrate exploded and combined views of a cooling apparatus 700 with fins 706 configured to retain a cooling fan 704 in a selected position relative to a heat exchanger 702. The cooling apparatus 700 may be further constructed by forming one or more retaining fins 712 of the multiple fins 706 in a configuration enabling the fans 704 to be retained relative to the heat exchanger 702. The embodiment shown in FIGS. 7A and 7B is further constructed by forming one or more plenum fins 714 of the multiple fins 706 in an arrangement configured to hold the fan 704 a plenum distance from the heat exchanger 702, forming a plenum space 710 between the fan 704 and the heat exchanger 702.

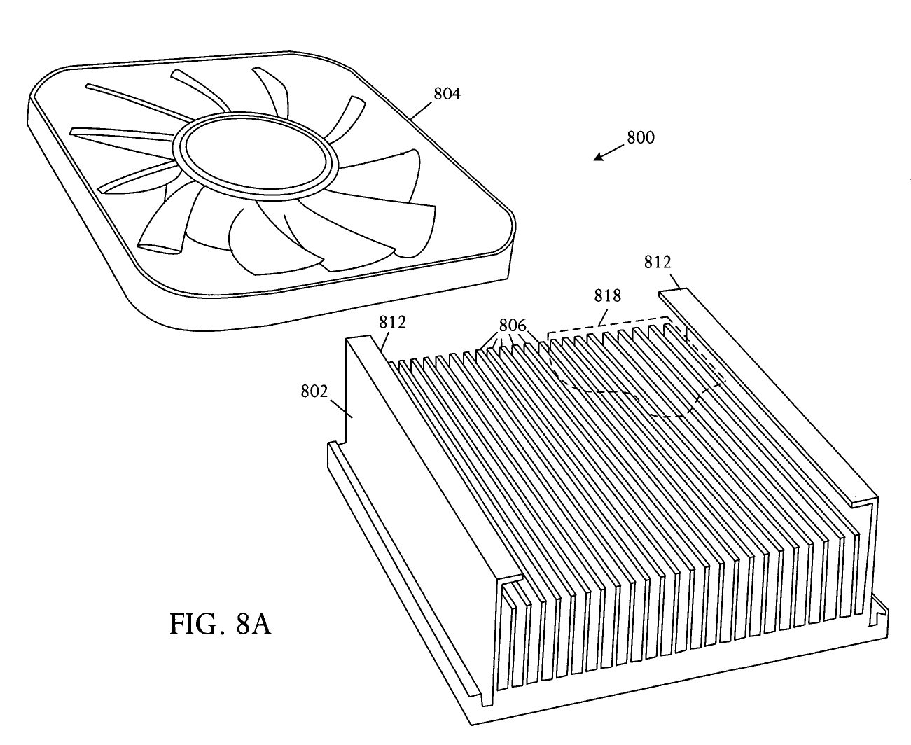

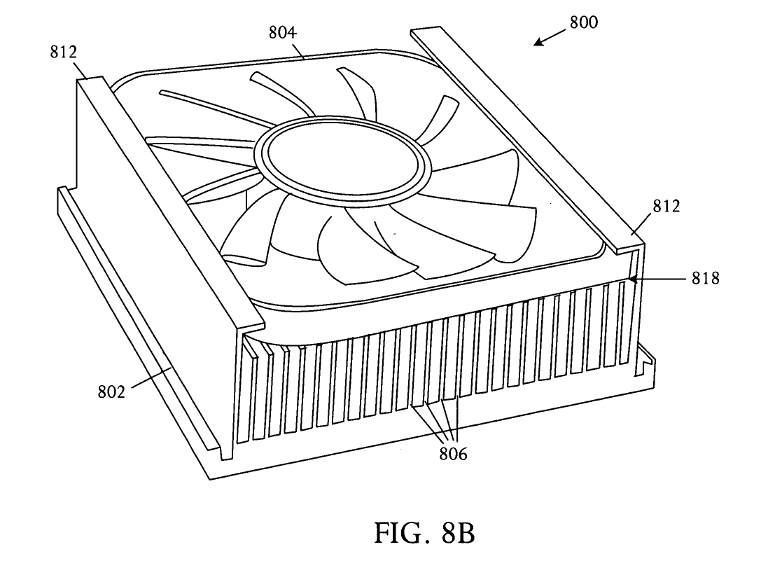

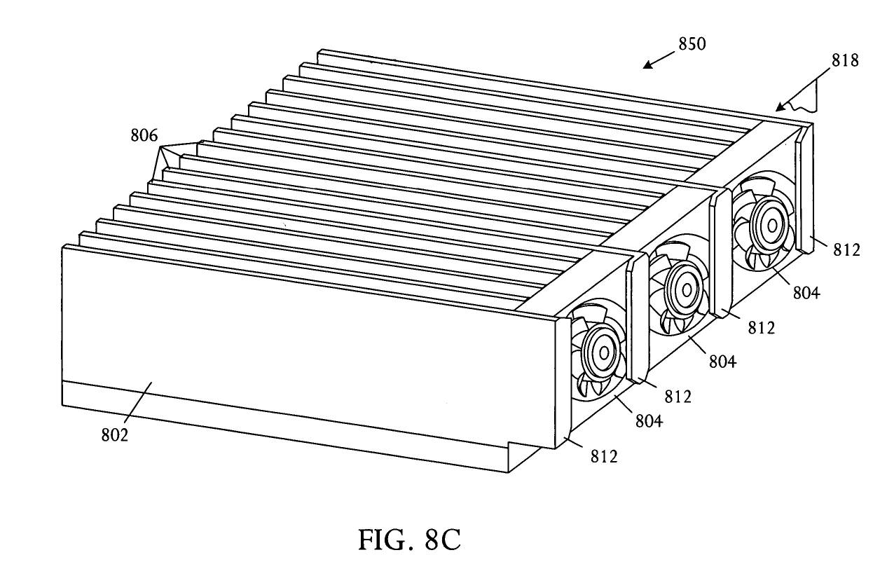

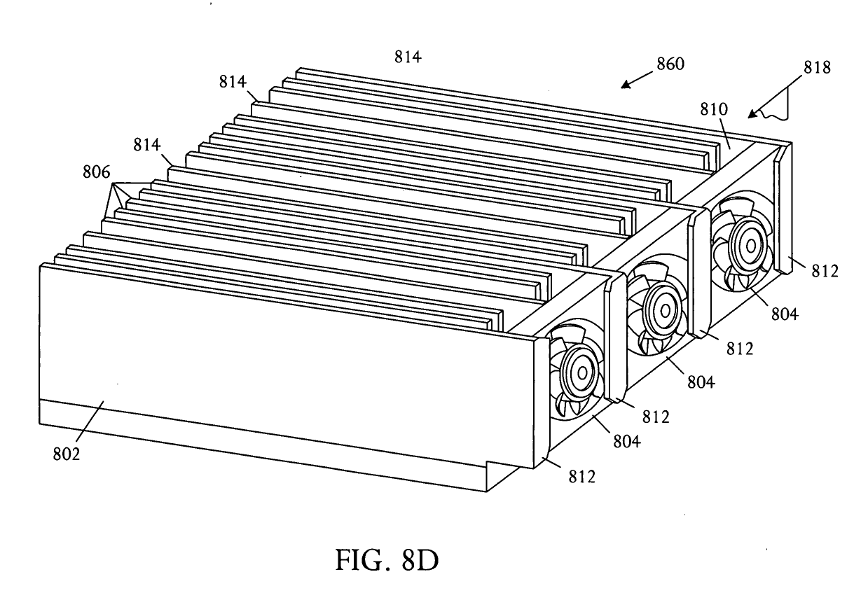

Referring to FIGS. 8A and 8B, perspective pictorial diagrams illustrate exploded and combined views of another embodiment of a cooling apparatus 800 with fins 806 configured to retain a cooling fan 804 in a selected position relative to a heat exchanger 802. The heat exchanger 802 comprises multiple fins 806 individually configured as planar sheets arranged in essentially parallel planes. The essentially parallel planes have only incidental deviation from parallel whereby the planes do not normally intersect throughout dimensions within the heat exchanger 802. The parallel planes extend to an edge 818 aligned in a plane intersecting the parallel planes. The cooling apparatus 800 further comprises one or more retaining fins 812. A retaining fin 812 is configured as a planar sheet arranged in a plane parallel with the other fins 806 although extends beyond the length of the other fins 806 with the extension beyond the other fins 806 appropriate to accommodate the size of a fan as well as structures on the retaining fin 812 for engaging and positioning the fan 804.

FIGS. 8A and 8B show a cooling apparatus embodiment with a single fan 804 mounted on a top surface of the heat exchanger 802. A myriad of other configurations may be implemented with any suitable number of fans mounted on any appropriate surface formed on the heat exchanger. For example, FIG. 8C is a perspective pictorial diagram showing an embodiment of a cooling apparatus 850 with multiple cooling fans 804 attached to a side surface of a heat exchanger 802. Although in the illustrative embodiments the heat exchangers predominantly have a rectangular shape, any suitable shape may be constructed, such as other parallelograms or various spherical or spheroid structures. For example, the edge 818 upon which a fan is mounted may not be perpendicular to the parallel planes of the fins, but rather may be at any suitable angle.

FIG. 8D is a perspective pictorial diagram illustrating an embodiment of a cooling apparatus 860 implementing a plenum space 810. One or more plenum fins 814 may be configured as planar sheets arranged in a plane parallel with the other fins 806 and extending between the edge 818 and the plenum fin or fins 814 which are formed to retain the fans 804 so that the plenum space 810 is formed between the fans 804 and the edge 818.

In some embodiments, the cooling apparatus may also include one or more fins arranged with structures for engaging power connectors from the fans as depicted in FIG. 5.

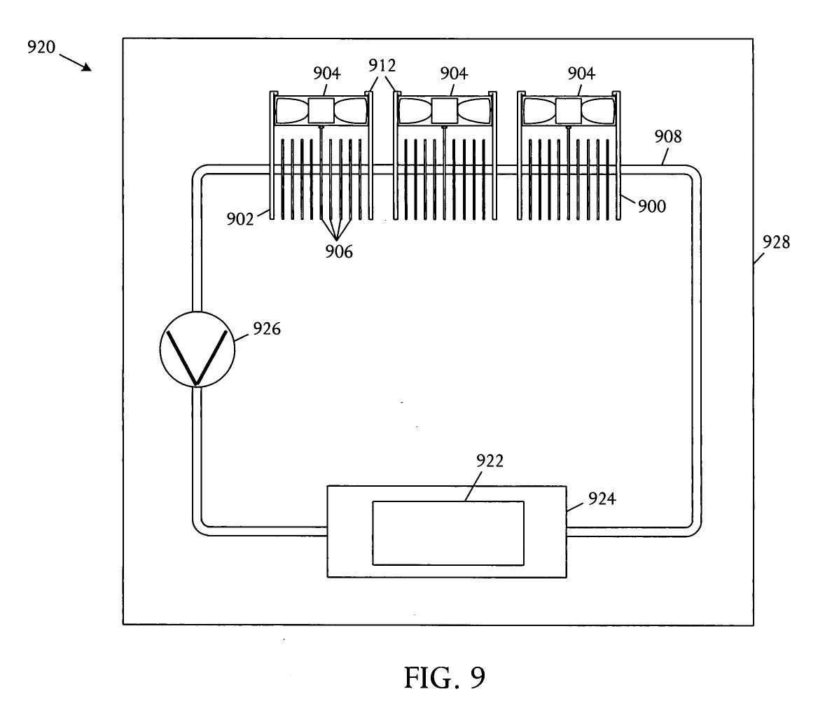

Referring to FIG. 9, a schematic mixed pictorial and block diagram illustrates an embodiment of an electronic system 920 that incorporates a cooling apparatus 900 with one or more fans 904 retained by heat exchanger fins 912. The electronic system 900 comprises one or more electronics components 922 and a liquid loop heat exchange cooling system 900.

The liquid loop heat exchange cooling system 900 comprises a closed loop tubing 908 and one or more cold plates 924 in intimate contact with selected electronics components 922 and coupled to the closed loop tubing 908. The cooling system 900 further comprises a pump 926 connected to the closed loop tubing 908 for driving a cooling fluid and a heat exchanger 902. The heat exchanger 902 has multiple fins 906 formed onto the closed loop tubing 908. Selected fins 912 are formed to position and retain one or more cooling fans 904. Cooling fans 904 force air across the heat exchanger fins 906 to remove energy from the liquid loop system 900.

The cooling apparatus 900 further comprises a cooling fluid which is adapted to circulate through the closed loop tubing 908 and transfer energy from the cold plate 922 to the heat exchanger 902.

In some embodiments, the electronic system 920 typically further comprises a chassis 928 containing the electronics components 922 and the liquid loop heat exchange system 900. The liquid loop heat exchange system 900 may be implemented in multiple various forms including forms illustrated in FIGS. 1 through 8.

While the present disclosure describes various embodiments, these embodiments are to be understood as illustrative and do not limit the claim scope. Many variations, modifications, additions and improvements of the described embodiments are possible. For example, those having ordinary skill in the art will readily implement the steps necessary to provide the structures and methods disclosed herein, and will understand that the process parameters, materials, and dimensions are given by way of example only. The parameters, materials, and dimensions can be varied to achieve the desired structure as well as modifications, which are within the scope of the claims. Variations and modifications of the embodiments disclosed herein may also be made while remaining within the scope of the following claims. For example, a few specific examples of fan structures, heat exchanger configurations, fan arrangements, and fan number are depicted. Any suitable arrangement of configuration of fans and heat exchangers may be implemented. The illustrative active heat exchangers may be used in any appropriate electronic system or device, such as suitable servers, computers, consumer electronics devices, communication systems and devices, storage system, and others.

In the claims, unless otherwise indicated the article “a” is to refer to “one or more than one.”

What is claimed is:

1. An apparatus comprising:
a heat exchanger comprising a tubing and multiple fins formed onto the tubing, the multiple fins being formed to position and retain at least one cooling fan.

2. The apparatus according to claim 1 further comprising:
at least one fin extended and folded for positioning and engaging power connectors.

3. The apparatus according to claim 1 further comprising:
at least one fin extended and folded for retaining the at least one fan and the power connectors for shock and vibration events.

4. The apparatus according to claim 1 further comprising:
at least one retaining fin of the multiple fins formed to retain the at least one fan in a position relative to the heat exchanger; and
at least one plenum fin of the multiple fins formed to hold the at least one fan a plenum distance from the heat exchanger whereby a plenum space is formed between the at least one fan and the heat exchanger.

5. The apparatus according to claim 1 further comprising:
a retaining fin of the multiple fins including a central planar fin extending to an end and flanges extending substantially perpendicular to the central planar fin in opposing directions whereby the flanges retain first and second cooling fans.

6. The apparatus according to claim 1 further comprising:
at least one cooling fan.

7. An electronic system comprising:
at least one electronics component; and
a liquid loop heat exchange cooling system comprising:
a closed loop tubing;
at least one cold plate in contact with selected ones of the at least one electronics component and coupled to the closed loop tubing;
a pump coupled to the closed loop tubing; and
a heat exchanger coupled to the closed loop tubing and multiple fins formed onto the closed loop tubing, the multiple fins being formed to position and retain at least one cooling fan.

8. The system according to claim 7 further comprising:
a cooling fluid adapted to circulate through the closed loop tubing and transfer energy from the at least one cold plate to the heat exchanger.

9. The system according to claim 7 further comprising:
a chassis containing the at least one electronics component and the liquid loop heat exchange system.

10. The system according to claim 7 further comprising:
the multiple fins extended and folded for positioning and engaging power connectors.

11. The system according to claim 7 further comprising:
the multiple fins extended and folded for retaining the at least one fan and the power connectors for shock and vibration events.

12. The system according to claim 7 further comprising:
at least one retaining fin of the multiple fins formed to retain the at least one fan in contact with the heat exchanger; and
at least one plenum fin of the multiple fins formed to hold the at least one fan a plenum distance from the heat exchanger whereby a plenum space is formed between the at least one fan and the heat exchanger.

13. The system according to claim 7 further comprising:
a retaining fin of the multiple fins including a central planar fin extending to an end and flanges extending substantially perpendicular to the central planar fin in opposing directions whereby the flanges retain first and second cooling fans.

14. The system according to claim 7 further comprising:
at least one cooling fan.

15. A method comprising:
forming multiple fins of a heat exchanger in a configuration adapted to position and hold at least one cooling fan.

16. The method according to claim 15 further comprising:
positioning the at least one cooling fan at a corresponding configured site; and
retaining the at least one cooling fan at the corresponding configured site.

17. The method according to claim 15 further comprising:
extending and folding the multiple fins to position and engage power connectors.

18. The method according to claim 15 further comprising:
extending and folding the multiple fins to retain the at least one fan and the power connectors for shock and vibration events.

19. The method according to claim 15 further comprising:
forming at least one retaining fin of the multiple fins to retain the at least one fan in a position relative to the heat exchanger; and
forming at least one plenum fin of the multiple fins to hold the at least one fan a plenum distance from the heat exchanger whereby a plenum space is formed between the at least one fan and the heat exchanger.

20. An apparatus comprising:
a heat exchanger comprising:
a plurality of fins individually configured as planar sheets arranged in parallel planes, the parallel planes extending to an edge aligned in a plane intersecting the parallel planes; and
at least one fin individually configured as at least one sheet arranged in a plane parallel with the parallel planes and extending beyond the edge, the at least one fin being formed to retain at least one fan against the edge of the parallel planes.

21. The apparatus according to claim 20 further comprising:
at least one fin configured to engage power connectors coupled to the at least one fan.

22. The apparatus according to claim 20 further comprising:
at least one fin individually configured as at least one sheet arranged in a plane parallel with the parallel planes and extending between the edge and the at least one fin formed to retain at least one fan whereby a plenum space is formed between the at least one fan and the edge.

23. An apparatus comprising:
means for transferring heat from a first fluid to a second fluid without
intermixing the fluids further comprising:
means for circulating the first fluid;
means for radiating heat from the first fluid to the second fluid, the heat radiating means further comprising means for positioning and retaining at least one fan relative to the heat radiating means.
